(19) United States
(12) Patent Application Publication
(10) Pub. No.: US 2004/0095723 A1
(43) Pub. Date: May 20, 2004

(54) Internal heat sink construction for CPU cabinet

(75) Inventors: Ming-Hu Tsai, Taoyuan Hsien (TW); Wei-Tsung Hsiao, Taoyuan Hsien (TW)

Correspondence Address: BRUCE H. TROXELL, Suite 1404, 5205 Leesburg Pike, Falls Church, VA, 22041, US

(73) Assignee: Enlight Corporation

(21) Appl. No.: 10/294,650

(22) Filed: Nov. 15, 2002

(51) Int. Cl. H05K 7/20

(52) U.S. Cl. 361/695

(57) ABSTRACT

An internal heat sinks construction for CPU cabinet at least comprises the cooling fans installed on the front wall and the rear wall of the cabinet casing. The front wall provides an air intake under the hard disk rack. The rear wall provides an air guide shield including one air intake and two air vents. There mounts a cooling in the vicinity of the air vents. The air guide shield further provides the air vent for the CPU heat fins and slots respectively so the airflow will cool them down independently. The cooling devices so arranged on the front wall and the rear wall offer a cooling airflow to effectively disperse the heat generated within CPU. The rear wall will produce air convection. This cooling system renders powerful and energetic airflow and convection to cool down the internal parts inside CPU rapidly.

### FIELD OF THE INVENTION

This invention relates to the heat sink construction and cooling system inside of CPU, in particular pertaining to the effective and swift dispersion of high heat generated and the energetic exchange of hot air with cold airflows.

### BACKGROUND OF THE INVENTION

It is inevitable that the operation of CPU will generate heat or high temperature inside and effective heat dissipation is critical to successful operation of CPU. In most cases, the heat-generating elements on the main board are CPU, hard disk and I/O slot. It is never overemphasized for the computer manufacturers to provide effective heat dissipation. In addition to the cooling effect, the powerful air convection and exchange are also important.

### SUMMARY OF THE INVENTION

The primary object of this invention is to provide a doubled direction heat sink construction. In addition to the cooling system furnished on the front wall and the rear wall to cool down the heat-generating elements, an air convection structure is assembled on the rear wall in an effort to achieve powerful air convection as well as the swift heat dispersion and dissipation.

Another object of this invention is to rapidly cool down the elements on the main board that are is easy to generate high heat in which the air guide shield is employed to bring in the external cold air directly flowing onto the CPU and interfaces inserted on the slots to produce a direct cooling efficiency.

Another object of this invention is to provide a temperature controller to the cooling fans which will increase or decrease the running speed of cooling fans directly in response to the high or low temperature it sense in CPU to ensure effective heat dissipation.

Another object of this invention is to have the cooling fans maintaining at fixed distance from the walls to ensure least noise generated by the cooling fans in running.

The objects and technology are explained in great detail with the aid of preferable embodiments as illustrated in the attached drawings.

### BRIEF DESCRIPTION OF THE DRAWINGS

FIG. 1 shows a stereo of the internal heat sink for CPU of this invention.

FIG. 2 shows a partial disassembly of the internal heat sink for CPU of this invention.

FIG. 3 shows a heat sensor is working inside of CPU.

FIG. 4 shows an appearance of the air guide shield of this invention.

FIG. 5 is a schematic diagram showing the air guide shied along with the cooling fan.

FIG. 6 shows an airflows and the ways to disperse the heat inside of CPU.

### DETAILED DESCRIPTION OF THE INVENTION

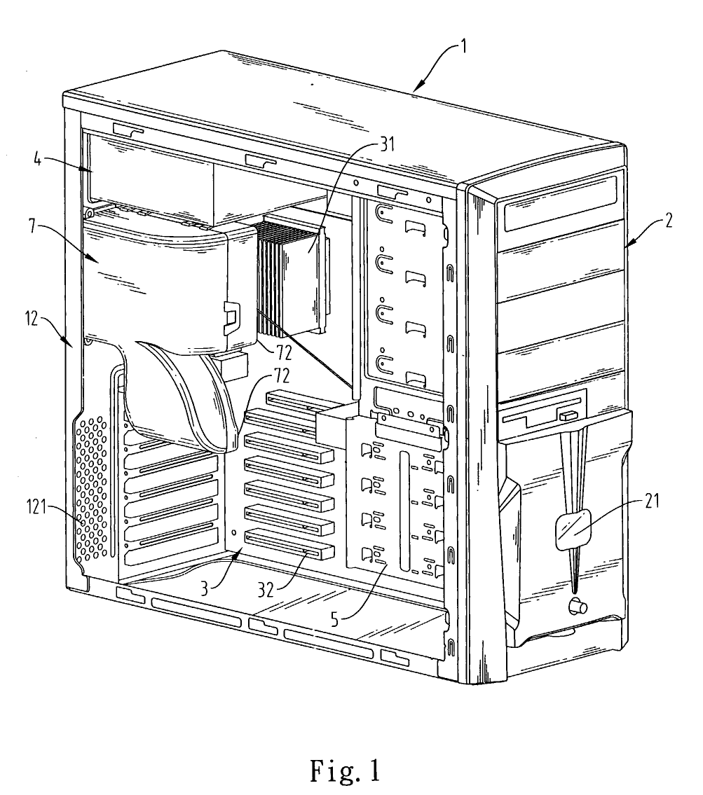

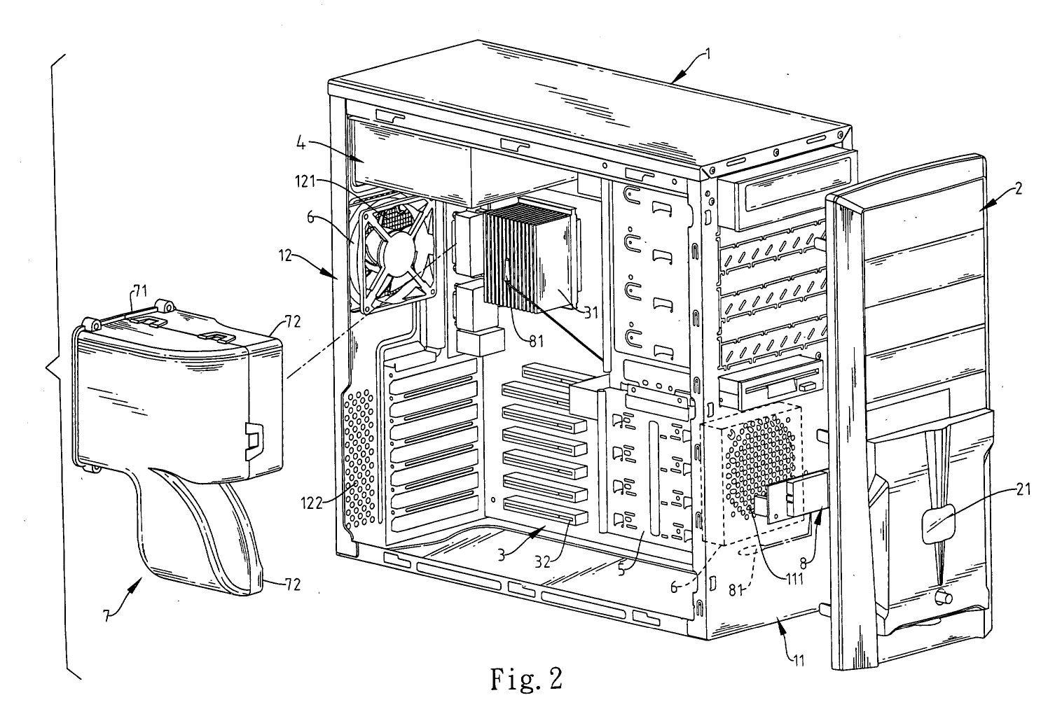

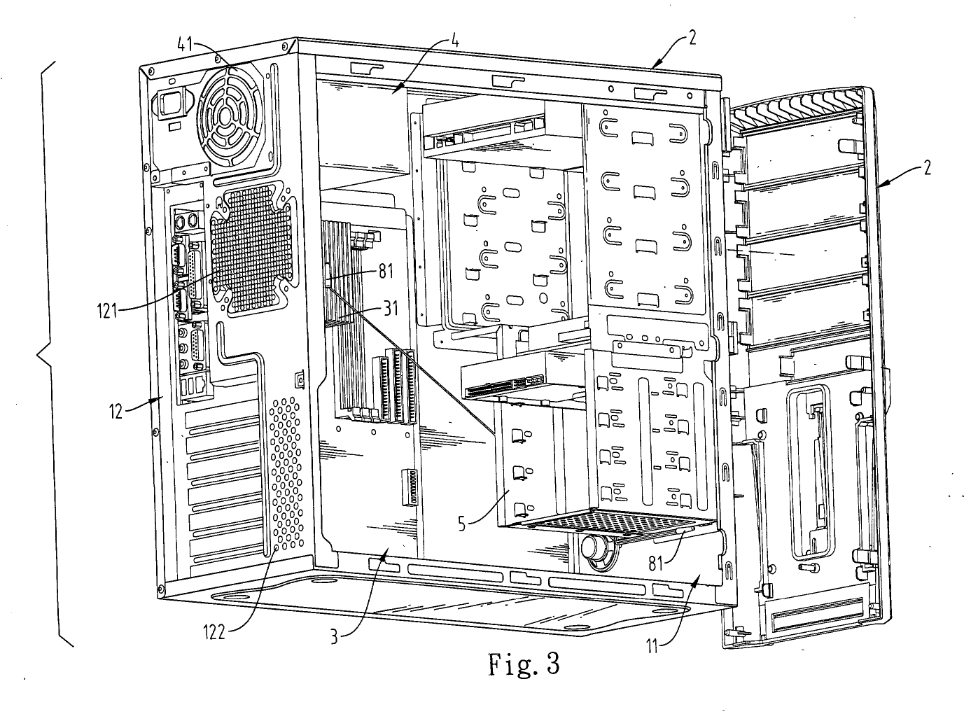

As shown in FIGS. 1 through 3, the main mission of the heat sink of this invention is to effectively disperse the heat within CPU. The casing 1 has a front wall 11 and front panel 2, and in between, there lodges a fan controller 8. The front wall 11 provides enough space for installing CD player and floppy disk. Below the floppy disk, several hard disks are mounted on the hard disk rack 5. The cooling fan 6 is erected on the hard disk rack 5, and the front wall 11 is perforated with a plurality of air intake holes 111. When the cooling fan 6 is running, it sucks the cold airflow from outside to cool down the temperature inside of CPU cabinet.

To dissipate the heat emitted from the CPU heat fin 31 and components inserted in the slot 32 of the main board 3, an air guide shield 7 is specially designed and furnished on the top of CPU heat fin 31 and slot 32 for leading in the cold air flow to cool down the temperature there.

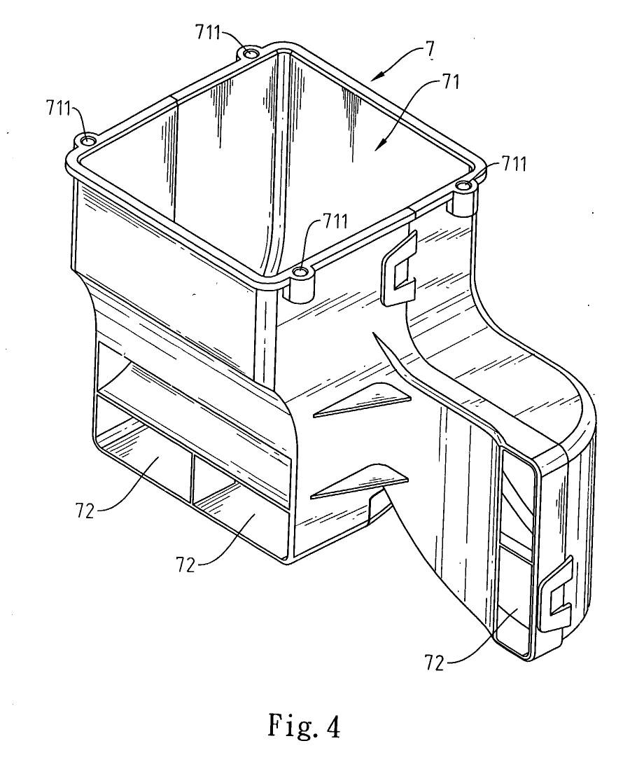

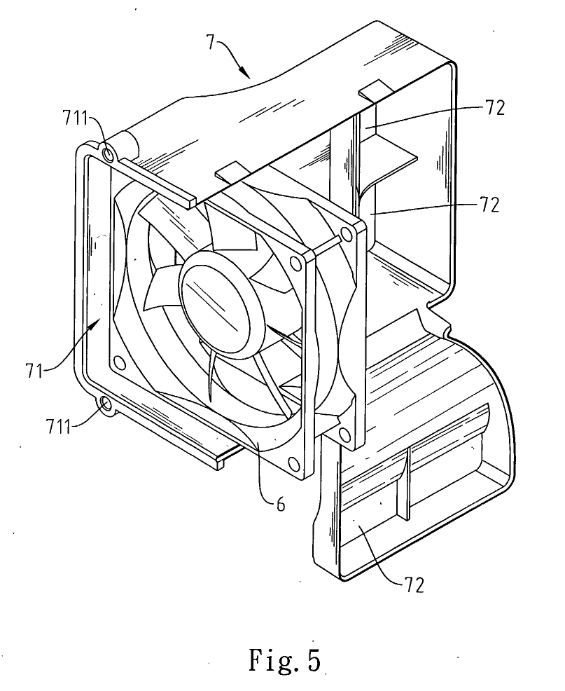

As shown in FIGS. 1, 2, 4 and 5, the air guide shield 7 has one air intake conduct 71 and two air vents 72. The air guide shield 7 provides the lock lug 711 on the margin along the air intake conduct 71 to be fastened to the rear wall 12 of the casing 1. The rear wall 12 provides the air intake holes 121 opened toward the air guide shield 7. The cold air sucked in from outside will be guided by the air guide shield 7 through the air vent 72 and directly flow toward the CPU heat fins 31 and the slot 32 and cool them down. The air guide shield 7 has a cooling fan 6 mounted at the air intake conduct 71. The cooling fan 6 keeps an adequate distance from the air intake conduct 71 and the rear wall 12 of the casing 1 so as to reduce the noise to the minimum when it is running.

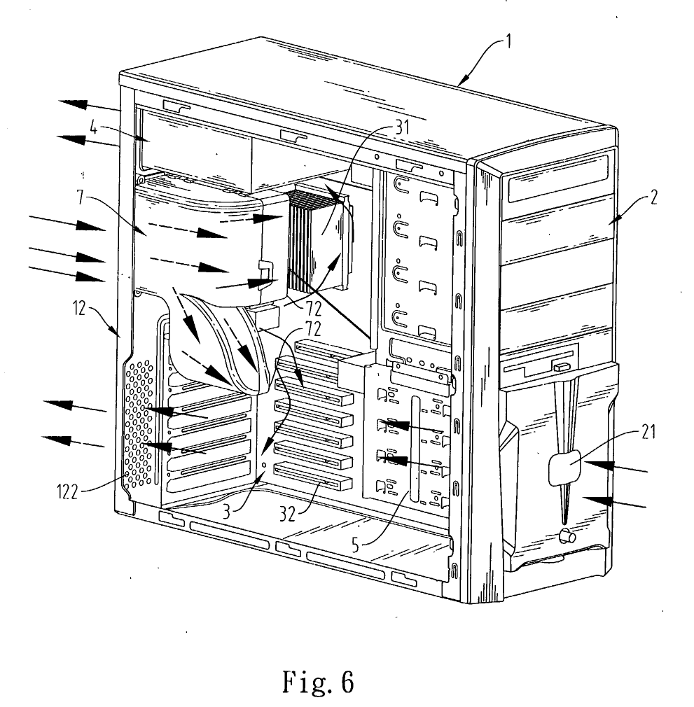

As illustrated in FIG. 6, the cooling fan 6 is arranged between the front wall 11 and the rear wall 12 and the cold air will flow in both from the front and the rear sides. Upon the completion of heat exchange, the exhaust fan 41 of the power supply will expel the heated air through the air intake hole 121. The air circulation will take all heated air out of the casing 1 with no residual heat left inside. The sensor 81 of the fan controller 8 is placed between CPU heat fin 31 and the hard disk rack 5 and the temperature sensed inside the cabinet will be displayed on the indication lamp 22 on the front panel 2. When the inside temperature is too high or the cooling fan is out of work, the indication lamp 22 will glitter and eventually speed up the running speed of the cooling fan 6.

1. An internal heat sink construction for CPU cabinet, mainly comprising a cooling fan installed between a front wall and a rear wall of a casing characterized in that:
said front wall provides space for mounting several hard disks, and below said hard disk, there is an air intake, an air guide shield is arranged to align with an air intake on said rear wall, said air guide shield has an air intake opening and two air vents, said air guide shield is fastened to said rear wall by a lock lug of an air intake conduct, said air guide shield provides a cooling fan and two air vents directing airflows to CPU heat fins and a slot for cooling respectively.

2. The internal heat sink construction for CPU cabinet of claim 1, wherein said cooling fan is so mounted to keep a fixed distance away from said air intake opening in an effort to reduce noise to minimum when said cooling fan is running.

3. The internal heat sink construction for CPU cabinet of claim 1, wherein a sensor for a fan controller is installed on said CPU heat fin and a hard disk rack, two major heat-generating components in CPU, said sensor can regulate speed of said cooling fan corresponding to temperature said sensor senses inside of said CPU cabinet.
